(19) United States
(12) Patent Application Publication
(10) Pub. No.: US 2024/0321678 A1
(43) Pub. Date: Sep. 26, 2024

(54) CHIP PACKAGING STRUCTURE, ELECTRONIC DEVICE AND CHIP PACKAGING METHOD

(71) Applicant: Smarter Silicon (Shanghai) Technologies Co., Ltd., Shanghai (CN)

(72) Inventors: SHIH-YUEH HUANG, Shanghai (CN); Kaiyou QIAN, Shanghai (CN)

(21) Appl. No.: 18/606,991

(22) Filed: Mar. 15, 2024

(30) Foreign Application Priority Data
Mar. 20, 2023 (CN) 202310273737.X

(51) Int. Cl. H01L 23/42; H01L 23/00; H01L 23/367

(52) U.S. Cl. CPC H01L 23/42; H01L 23/367; H01L 24/29; H01L 24/32; H01L 24/83; H01L 2224/29076; H01L 2224/32245; H01L 2224/83201

(57) ABSTRACT

A chip packaging structure includes a chip, a heat sink, and a thermal conductive layer. The heat sink and the chip are fixed by thermal contact through the thermal conductive layer. The thermal conductive layer includes a stress buffer layer and a plurality of thermal conductive protrusions located in the stress buffer layer. Bottoms of the plurality of thermal conductive protrusions are located on a surface of the chip or a surface of the heat sink.

### CROSS-REFERENCES TO RELATED APPLICATIONS

This application claims priority of Chinese Patent Application No.: 202310273737.X, filed on Mar. 20, 2023, the entire content of which is hereby incorporated by reference.

### FIELD OF THE DISCLOSURE

The present disclosure generally relates to the field of chip packaging technology and, more particularly, relates to a chip packaging structure, an electronic device, and a chip packaging method.

### BACKGROUND

With continuous development of science and technology, more and more electronic devices are widely used in people's daily life and work, bringing great convenience to people's daily life and work, and becoming indispensable and important tools for people nowadays.

A chip is a control core for an electronic device to realize various functions. To realize interconnections between a chip and external circuits and to prevent the chip from being damaged, the chip needs to be packaged and protected. In existing technology, after a chip is packaged and protected, the resulting chip packaging structure may have poor heat dissipation performance.

### SUMMARY

One aspect of the present disclosure includes a chip packaging structure. The chip packaging structure includes a chip, a heat sink, and a thermal conductive layer. The heat sink and the chip are fixed by thermal contact through the thermal conductive layer. The thermal conductive layer includes a stress buffer layer and a plurality of thermal conductive protrusions located in the stress buffer layer. Bottoms of the plurality of thermal conductive protrusions are located on a surface of the chip or a surface of the heat sink.

Another aspect of the present disclosure includes an electronic device. The electronic device includes a chip packaging structure. The chip packaging structure includes a chip, a heat sink, and a thermal conductive layer. The heat sink and the chip are fixed by thermal contact through the thermal conductive layer. The thermal conductive layer includes a stress buffer layer and a plurality of thermal conductive protrusions located in the stress buffer layer. Bottoms of the plurality of thermal conductive protrusions are located on a surface of the chip or a surface of the heat sink.

Another aspect of the present disclosure includes a chip packaging method. The method includes providing a chip, providing a heat sink, and fixing the chip and the heat sink by thermal contact through a thermal conductive layer. The thermal conductive layer includes a stress buffer layer and a plurality of thermal conductive protrusions located in the stress buffer layer, and bottoms of the plurality of thermal conductive protrusions are located on a surface of the chip or a surface of the heat sink.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic diagram of a chip packaging structure consistent with the disclosed embodiments of the present disclosure;

FIG. 2 illustrates a schematic diagram of another chip packaging structure consistent with the disclosed embodiments of the present disclosure;

FIG. 3 illustrates a schematic diagram of another chip packaging structure consistent with the disclosed embodiments of the present disclosure;

FIG. 4 illustrates a cross-sectional view of a thermal conductive protrusion consistent with the disclosed embodiments of the present disclosure;

FIG. 5 illustrates a schematic diagram of another chip packaging structure consistent with the disclosed embodiments of the present disclosure;

FIG. 6 illustrates a schematic diagram of another chip packaging structure consistent with the disclosed embodiments of the present disclosure;

FIG. 7 illustrates a schematic diagram of another chip packaging structure consistent with the disclosed embodiments of the present disclosure;

FIG. 8 illustrates a schematic structural diagram of an electronic device consistent with the disclosed embodiments of the present disclosure;

FIG. 9 illustrates a method flow chart of a chip packaging method consistent with the disclosed embodiments of the present disclosure;

FIG. 10 illustrates a method flow chart for performing thermal contact fixation on a chip and a heat sink through a thermal conductive layer consistent with the disclosed embodiments of the present disclosure; and

FIG. 11 illustrates a schematic principle diagram of providing a stress buffer layer on a surface of a chip consistent with the disclosed embodiments of the present disclosure.

### DETAILED DESCRIPTION

To make the objectives, technical solutions and advantages of the present disclosure more clear and explicit, the present disclosure is described in further detail with accompanying drawings and embodiments. It should be understood that the specific exemplary embodiments described herein are only for explaining the present disclosure and are not intended to limit the present disclosure.

It should be noted that relative arrangements of components and steps, numerical expressions and numerical values set forth in exemplary embodiments are for illustration purpose only and are not intended to limit the present disclosure unless otherwise specified. Techniques, methods and apparatus known to the skilled in the relevant art may not be discussed in detail, but these techniques, methods and apparatus should be considered as a part of the specification, where appropriate.

In a conventional chip packaging structure, a chip and a packaging substrate are generally sealed and fixed through thermal conductive adhesive, and the chip is sealed and protected through a shell fixed to a packaging substrate. A main heat dissipation path of the chip may be conducted to the packaging substrate through a backside of the chip. For the chip packaging structure, to improve the heat dissipation efficiency, the heat dissipation path may be shortened by reducing the thickness of the thermal conductive adhesive in the chip packaging structure, or the thermal conductive adhesive may be replaced a thermal conductive adhesive with higher thermal conductivity.

For the approach of reducing the thickness of thermal conductive adhesive between the chip and the packaging substrate, on the one hand, reducing the thickness of thermal conductive adhesive may lead to insufficient coverage area of the thermal conductive adhesive, affecting the bonding stability of the chip on the surface of the packaging substrate; and on the other hand, thermal conductive adhesive may not be able to effectively buffer the stress on the chip when the thermal conductive adhesive is deformed by heat, and warping problems of the chip may appear.

For the approach of using the thermal conductive adhesive with high thermal conductivity, on the one hand, the improvement in heat dissipation efficiency may be limited; and on the other hand, the cost of thermal conductive adhesive with high thermal conductivity may be relatively high, and the cost of chip packaging may increase.

To address the above problems, the present disclosure provides a chip packaging structure, an electronic device, and a chip packaging method. The chip is packaged through a heat sink, and the heat sink and the chip are fixed by thermal contact through a thermal conductive layer. While the heat sink is used to package and protect the chip, heat dissipation of the chip may be improved simultaneously. Moreover, the thermal conductive layer includes a stress buffer layer and a thermal conductive protrusion located in the stress buffer layer. On the one hand, the stress buffer layer may be used to solve the warping problem of the chip caused by changes in temperature and pressure during the packaging process. On the other hand, the thermal conductive protrusion may increase the thermal contact area between the chip and the heat sink, improving the heat dissipation rate.

To make the above objects, features and advantages more obvious and understandable, the present disclosure will make descriptions in further detail below in conjunction with accompanying drawings and specific implementations.

FIG. 1 illustrates a schematic diagram of a chip packaging structure consistent with the disclosed embodiments of the present disclosure. Referring to FIG. 1, the chip packaging structure includes a chip 11 and a heat sink 12.

The heat sink 12 and the chip 11 are fixed by thermal contact through a thermal conductive layer 13. The thermal conductive layer 13 includes a stress buffer layer 131 and a plurality of thermal conductive protrusions 132 located in the stress buffer layer 131. The bottom of the thermal conductive protrusion 132 is located on a surface of the chip 11 or the heat sink 12.

In the chip packaging structure provided by one embodiment of the present disclosure, the chip 11 is packaged through the heat sink 12. The heat sink 12 and the chip 11 are fixed by thermal contact through the thermal conductive layer 13. While the chip 11 is packaged and protected through the heat sink 12, good heat dissipation of the chip 11 may also be achieved. Moreover, the thermal conductive layer 13 includes the stress buffer layer 131 and the thermal conductive protrusion 132 located in the stress buffer layer 131. On the one hand, the stress buffer layer 131 may be used to solve the warping problem of the chip 11 caused by changes in temperature and pressure during the packaging process. On the other hand, the thermal conductive protrusion 132 may increase the thermal contact area between the chip 11 and the heat sink 12, improving the heat dissipation rate.

The bottom of the thermal conductive protrusion 132 may be in contact with the chip 11 or the heat sink 12 respectively. As an example for illustration, in the configuration shown in FIG. 1, the bottom of each thermal conductive protrusion 132 is in contact with the chip 11.

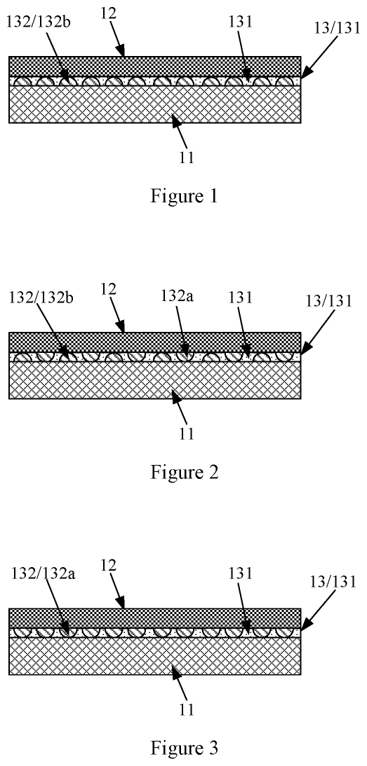

FIG. 2 illustrates a schematic diagram of another chip packaging structure consistent with the disclosed embodiments of the present disclosure. As an example for illustration, in the configuration shown in FIG. 2, the bottoms of part of the thermal conductive protrusions 132 are in contact with the chip 11, and the bottoms of other part of the thermal conductive protrusions 132 are in contact with the heat sink 12.

FIG. 3 illustrates a schematic diagram of another chip packaging structure consistent with the disclosed embodiments of the present disclosure. As an example for illustration, in the configuration shown in FIG. 3, the bottom of each thermal conductive protrusion 132 is in contact with the heat sink 12.

In the present disclosure, the bottom of the thermal conductive protrusion 132 may be in contact with the chip 11, or may be in contact with the heat sink 12.

The plurality of thermal conductive protrusions 132 are set to include at least one of a first thermal conductive protrusion 132a and a second thermal conductive protrusion 132b. The bottom of the first thermal conductive protrusion 132a is located on the surface of the heat sink 12. The top of the first thermal conductive protrusion 132a faces the chip 11. The top of the first thermal conductive protrusion 132a may be fixed to the chip 11 by welding, or fixed to the chip 11 by adhesion through the stress buffer layer 131. The bottom of the second thermal conductive protrusion 132b is located on the surface of the chip 11. The top of the second thermal conductive protrusion 132b faces the heat sink 12. The top of the second thermal conductive protrusion 132b may be fixed to the heat sink 12 by welding, or fixed to the heat sink 12 by adhesion through the stress buffer layer 131.

The stress buffer layer 131 is made of a material with viscosity and elasticity. On the one hand, the stress buffer layer 131 may fix the heat sink 12 and the chip 11 by adhesion, and on the other hand, the stress buffer layer 131 may have good flexible buffering performance. Based on the good flexible buffering performance, the stress buffer layer 131 may buffer the stress on the chip 11 during the process of fixing the heat sink 12 and the chip 11 by thermal contact. In addition, after the packaging is completed, the stress buffer layer 131 may buffer impact forces transmitted to the chip 11 when the chip packaging structure is impacted by external forces.

Moreover, the stress buffer layer 131 is made of a high thermal conductivity material. Based on the high thermal conductivity, the heat of the chip 11 may be quickly conducted to the heat sink 12. Accordingly, the heat dissipation efficiency of the chip 11 may be improved.

Optionally, the material of the stress buffer layer 131 may include a base material with viscosity and elasticity, such as silicone grease, rubber, synthetic polymer compound, or a combination thereof. Furthermore, the base material of the stress buffer layer 131 may be mixed with additives. The additives may be used to achieve one or more of the following functions: enhancing weather resistance, adjusting flexibility, adjusting viscosity, and increasing thermal conductivity. The additives may include ceramic powder, magnesium oxide powder, metal powder, mica powder, talc powder, preservative, coupling agent, stabilizer, or a combination thereof.

In one embodiment, the stress buffer layer 131 may be a material with a single-layer structure, with viscosity and elasticity, or the stress buffer layer 131 may be a single layer of thermal conductive adhesive.

The stress buffer layer 131 may include two first film layers and a second film layer located between the two first film layers. The first film layer on one side of the second film layer is used for fixing with the chip 11 by adhesion, and the first film layer on the other side the second film layer is used for fixing with the heat sink by adhesion. The viscosity of the first film layer may be greater than the viscosity of the second film layer, such that the chip 11 and the heat sink 12 may be reliably fixed through the stress buffer layer 131 by adhesion.

To improve the thermal conductivity of the stress buffer layer 131, the thermal conductivity of the second film layer may be set to be greater than the thermal conductivity of the first film layer. Accordingly, while the chip 11 and the heat sink 12 are fixed by adhesion through the stress buffer layer 131, the heat dissipation effect of the chip 11 may be improved.

To make the stress buffer layer 131 to better fix the heat sink 12 and the chip by adhesion, and to improve the stress buffer effect the stress buffer layer 131, the elasticity of the second film layer may be set to be greater than the elasticity of the first film layer. Accordingly, while the chip 11 and the heat sink 12 are fixed by adhesion through the stress buffer layer 131, the elastic buffering effect of the chip 11 may be improved.

The first thermal conductive protrusions 132a may be directly formed on the surface of the heat sink 12 with the heat sink 12 as a carrier. The second thermal conductive protrusions 132b may be directly formed on the surface of the chip 11 with the chip 11 as a carrier.

Based on requirements, the chip packaging structure may be set to include at least one of the first thermal conductive protrusion 132a and the second thermal conductive protrusion 132b. The present disclosure does not limit a specific implementation approach, and references may be made to FIGS. 1 to 3.

In the configurations shown in FIGS. 1 to 3, the top of the thermal conductive protrusion 132 is in direct contact with the chip 11 or the heat sink 12 opposite to the thermal conductive protrusion 132. In these configurations, the top of the thermal conductive protrusion 132 is directly fixed to the opposite chip 11 or the heat sink 12 by welding. In some other configurations, a gap may exist between the top of the thermal conductive protrusion 132 and the chip 11 or the heat sink 12 opposite to the thermal conductive protrusions 132. The gap may be filled with the stress buffer layer 131. The top of the thermal conductive protrusion 132 and the chip 11 or the heat sink 12 opposite to the thermal conductive protrusion 132 may be fixed by adhesion through the stress buffer layer 131.

Different from a conventional chip packaging structure, in one embodiment, the first thermal conductive protrusions 132a may be formed on the surface of the heat sink 12 facing the chip 11, and/or the second thermal conductive protrusions 132b may be formed on the surface of the chip 11 facing the heat sink 12. The heat sink 12 and the chip 11 may be fixed by adhesion through the stress buffer layer 131. In this way, the thermal contact area between the chip 11 and the heat sink 12 may be increased through the thermal conductive protrusions 132, and the heat dissipation efficiency of the chip 11 may also be improved. In addition, the stress buffer layer 131 may also solve the warping problem of the chip 11 due to changes in temperature and/or stress during the packaging process, and the reliability and stability of the packaging of the chip 11 may be improved.

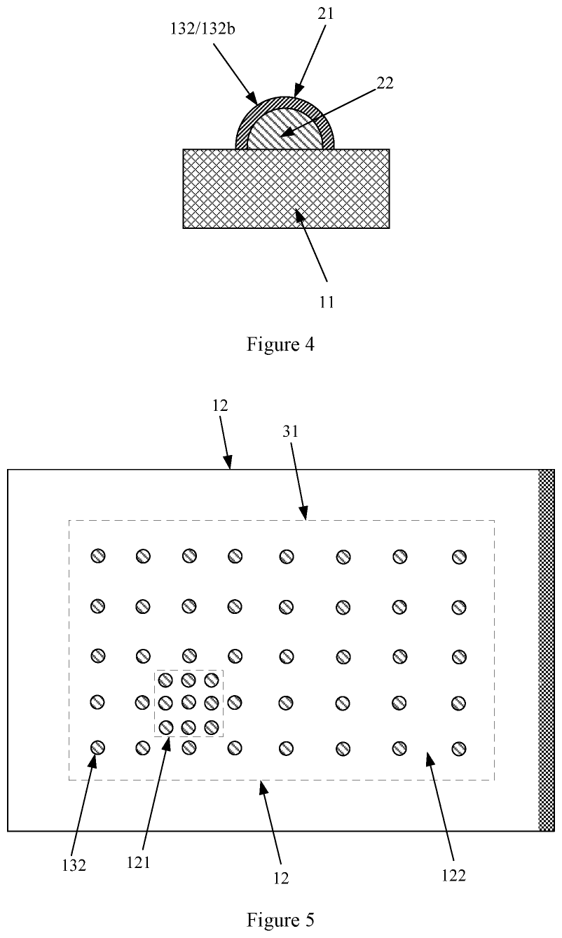

FIG. 4 illustrates a cross-sectional view of a thermal conductive protrusion consistent with the disclosed embodiments of the present disclosure. When the top of the thermal conductive protrusion 132 is welded to the surface of the chip 11 or to the surface of the heat sink 12, the thermal conductive protrusion 132 may have a structure as shown in FIG. 4. As an example, FIG. 4 illustrates a structure of the second thermal conductive protrusion 132b on the surface of the chip 11. The thermal conductive protrusion 132 includes a thermal conductive base material 22 and a solder layer 21 covering the thermal conductive base material 22. The melting point of the solder layer 21 may be lower than the melting point of the thermal conductive base material 22. In this case, the top of the second thermal conductive protrusion 132b may be directly fixed by welding to the heat sink 12 based on the solder layer 21.

In the configuration shown in FIG. 4, the second thermal conductive protrusion 132b is taken as an example for illustration. The configuration shown in FIG. 4 may also be used for the first heat conductive protrusion 132a. In this case, the first thermal conductive protrusion 132a may be directly formed on the surface of the heat sink 12, and the top of the first thermal conductive protrusion 132a may be directly fixed by welding to the chip 11 based on the solder layer 21.

In one embodiment, when the top of the thermal conductive protrusion 132 is directly fixed by welding to the chip 11 or the heat sink 12, the thermal conductive protrusion 132 may include: the thermal conductive base material 22 and the solder layer 21 covering the thermal conductive base material 22. The melting point of the solder layer 21 is lower than the melting point of the thermal conductive base material 22. In this way, welding fixation may be achieved based on a low-temperature welding process, and the warping problem of the chip 11 during a welding fixation process caused by high welding temperature may be avoided.

The solder layer 21 is a low-temperature soldering material, and the soldering temperature may be less than approximately 180° C. In this case, when the chip 11 and the heat sink 12 are fixed by welding based on the solder layer 21, the welding fixation may be performed based on a low-temperature welding process. Accordingly, the impact of changes in stress and temperature inside the chip during a high-temperature welding process may be avoided, and the warping problem of the chip 11 may also be avoided.

In one embodiment, the bottom of the thermal conductive protrusion 132 is located on one of the chip 11 and the heat sink 12, and the stress buffer layer 131 is disposed between the top of the thermal conductive protrusion 132 and the other of the chip 11 and the heat sink 12. In this case, the thermal conductive protrusion 132 may be made of the thermal conductive base material 22 only, without the solder layer 21. The thermal conductive base material 22 may be a metal bump or other high thermal conductivity material bump.

The solder layer 21 may be SnBi low-temperature solder. Since the soldering temperature of the SnBi low-temperature solder is relatively low, the thermal conductive protrusion 132 and the heat sink 12 or the chip 11 may be fixed by welding based on low-temperature welding.

TABLE 1

| | Thermal | | | |
|---|---|---|---|---|
| | conductive | | | |
| Material | adhesive | SnBi | SnBiAg | SnPb37 |
| Thermal | 3.8-6.8 | 21 | 37.4 | 50 |
| conductivity | | | | |
| Comments | — | — | Contains Ag, | Contains lead, not |
| | | | high price | environmentally |
| | | | | friendly |

As shown in Table 1, in the chip packaging structure provided by one embodiment of the present disclosure, the stress buffer layer 131 may be made of thermal conductive adhesive, with thermal conductivity in a range of approximately 3.8-6.8. The solder layer 21 may be SnBi low-temperature solder with thermal conductivity of approximately 21. The solder layer 21 may have a low welding temperature, and may be welded based on a low-temperature welding process. Compared with other solders (such as SnBiAg and SnPb37 in Table 1), SnBi low-temperature solder does not contain silver, and has low material cost. Since SnBi low-temperature solder does not contain lead, environmental protection requirements may be met by using SnBi low-temperature solder.

TABLE 2

| | | Typical | |
|---|---|---|---|
| Category | Series | components | Application |
| Low temperature | Sn—Bi eutectic, | SnBi58 | Low-temperature welding |
| lead-free solder | near-eutectic, | SnBi57Ag1 | processes (welding of high- |
| | hypoeutectic alloys, | SnBi35Ag1 | frequency heads, lightning |
| | and Sn—In series | SnBi30Cu0.5 | protection components, flexible, |
| | alloys | SnIn52 etc. | secondary low-temperature |
| | | | reflow, multi-layer circuit |
| | | | boards, etc.), and assembly |
| | | | welding of lead-free electronic |
| | | | products, etc. |

The solder layer 21 is not limited to SnBi low-temperature solder. The solder layer 21 may also be low-temperature lead-free solder shown in Table 2. The low-temperature lead-free solder may include Sn—Bi eutectic, near-eutectic, hypoeutectic alloys and Sn—In series alloys, etc. Main components of the low-temperature lead-free solder may include SnBi58, SnBi57Ag1, SnBi35Ag1, SnBi30Cu0.5, SnIn52, or a combination thereof. The low-temperature lead-free solder may be used in low-temperature welding processes (welding of high-frequency heads, lightning protection components, flexible, secondary low-temperature reflow, multi-layer circuit boards, etc.) and assembly welding of lead-free electronic products, etc.

In the chip packaging structure, when performing thermal contact fixation between the chip 11 and the heat sink 12, the stress buffer layer 131 may be provided between the chip 11 and the heat sink 12. The stress buffer layer 131 may absorb the stress on the chip 11 when the chip 11 and the heat sink 12 are fixed by thermal contact, and the warping problem of the chip 11 may be avoided. As described above, the thermal conductive protrusion 132 may be directly formed on the surface of one of the chip 11 and the heat dissipation chip 12. Thermal contact fixation between the chip 11 and the heat sink 12 may be performed by two approaches. In the first approach, the top of the thermal conductive protrusion 132 is fixed to the other of the chip 11 and the heat dissipation chip 12, and the stress buffer layer 131 is filled between the chip 11 and the heat dissipation chip 12. In the second approach, the chip 11 and the heat dissipation chip 12 are directly fixed by adhesion through the stress buffer layer 131. The stress buffer layer 131 exists between the top of the thermal conductive protrusion 132 and the other of the chip 11 and the heat dissipation chip 12. In the present disclosure, the thermal conductive protrusions 132 are not limited to the partial spherical protrusions shown in FIGS. 1-4. In some other embodiments, the thermal conductive protrusions 132 may also be cylindrical protrusions, or protrusions with other geometric shapes. The present disclosure does not limit a specific shape of the thermal conductive protrusions 132.

In one embodiment, the approach for the thermal contact between the heat sink 12 and the chip 11 includes: welding fixation based on the thermal conductive protrusions 132, and adhesion fixation based on the stress buffer layer 131 between the thermal contact between the heat sink 12 and the chip 11. In this case, during a welding fixation process of the heat sink 12 and the chip 11 through the thermal conductive protrusions 132, the pressure exerted by the heat sink 12 on the chip 11 and the change in welding temperature may cause the chip to warp. In one embodiment, the buffer layer 131 may buffer the impact of pressure and temperature changes on the chip 11 during the welding process, avoiding the warping problem of the chip 11.

In another embodiment, the approach for the thermal contact between the heat sink 12 and the chip 11 does not require welding. The stress buffer layer 131 is disposed between the top of the thermal conductive protrusion 132 and the chip 11 or the heat sink 12 that is opposite to the thermal conductive protrusion 132. The chip 11 and the heat sink 12 may be fixed by adhesion based on the stress buffer layer 131 between the chip 11 and the heat sink 12. In this case, during the adhesion fixation process of the heat sink 12 and the chip 11 through the stress buffer layer 131, the buffer layer 131 may buffer the stress exerted on the chip 11 during the adhesion fixation process, avoiding the warping problem of the chip 11.

As described above, after the packaging is completed, when the chip packaging structure is impacted by an external force, the stress buffer layer 131 may buffer the impact force exerted on the chip 11 and avoid the warping problem caused by the impact force. In addition, the stress buffer layer 131 may also surround the thermal conductive protrusion 131 to protect the thermal conductive protrusion. Accordingly, reliable thermal contact and fixation between the thermal conductive protrusion and the heat sink 12 or the chip 11 may be achieved.

FIG. 5 illustrates a schematic diagram of another chip packaging structure consistent with the disclosed embodiments of the present disclosure. Based on the above embodiments, in the configuration shown in FIG. 5, the side surface of the chip 11 facing the heat sink 12 includes a first area 121 and a second area 122. The operating power of the circuit in the first area 121 is greater than the operating power of the circuit in the second area 122. In the region where the chip 11 is opposite to the heat sink 12, the thermal conductive protrusions 132 corresponding to the first area 121 have a first distribution density, and the thermal conductive protrusions 132 corresponding to the second area 122 have a second distribution density. The first distribution density is greater than the second distribution density.

Since the operating power of the circuit in the first area 121 is greater than the operating power of the circuit in the second area 122, when the chip 11 is in operation, the heat generated in the first area 121 may be relatively high. In the configuration shown in FIG. 5, thermal conductive protrusions 132 with a higher distribution density are provided corresponding to the first area 121. Accordingly, the heat dissipation efficiency of the high heat generating area of the chip 11 may be improved.

No matter whether one or each of the heat sink 12 and the chip 11 is provided with thermal conductive protrusions 132, higher distribution density of the thermal conductive protrusions 132 may be set for the first area 121 (high heat generating area) with high operating power on the surface of the chip 11. The heat dissipation efficiency of the chip 11 may thus be improved. In this approach, it is preferable to directly dispose the thermal conductive protrusions 132 on the surface of the chip 11, such that differentiated distribution density of the thermal conductive protrusions 132 corresponding to different areas of the chip 11 may be achieved.

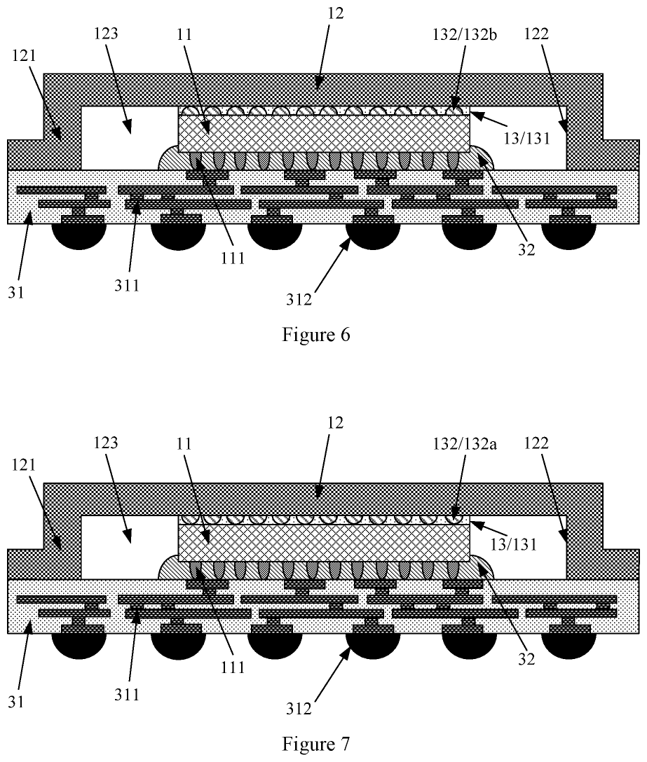

FIG. 6 illustrates a schematic diagram of another chip packaging structure consistent with the disclosed embodiments of the present disclosure. Based on the above embodiments, in the configuration shown in FIG. 6, the heat sink 12 includes a groove 121. The sidewall 122 of the groove 121 is sealed and fixed with a packaging substrate 31 to form a cavity 123;

The chip 11 is located in the cavity 123. The chip 11 includes a first surface and a second surface opposite to the first surface. The first surface is fixed on the surface of the packaging substrate 31, and the second surface faces the groove bottom surface of the heat sink 12. The second surface of the chip 11 and the groove bottom surface of the heat sink 12 may be fixed by thermal contact through the thermal conductive layer 13. The bottom of the thermal conductive protrusion 132 in the thermal conductive layer 13 may be located on the second surface of the chip 11 or on the bottom surface of the groove of the heat sink 12.

As shown in FIG. 6, the heat sink 12 includes the groove 121, and the periphery of the heat sink 12 is sealed and fixed with the packaging substrate 31. The chip 11 is packaged in the sealed space formed by the groove 121 and the packaging substrate 31. Sealing protection of the chip 11 may thus be achieved.

As shown in FIG. 6, the first surface of the chip 11 includes pins 111. The pins 111 are electrically connected to the interconnection circuit 311 in the packaging substrate 31. The packaging substrate 31 is disposed with an external terminal 312 on a surface of a side of the packaging substrate 31 facing away from the chip 11. The external terminal 312 is electrically connected to the interconnection circuit 311, and is configured to connect the chip packaging structure and external circuits. To improve the reliability of the connection between the chip 11 and the packaging substrate 31 and to improve the heat dissipation efficiency of the chip 11, thermal conductive adhesive 32 is filled between the chip 11 and the packaging substrate 31. The external terminal 312 may be a solder ball.

After the pins 111 of the chip 11 and the packaging substrate 31 are fixed by welding, the thermal conductive adhesive 32 may be filled between the chip 11 and the packaging substrate 31 to achieve good thermal contact fixation between the chip 11 and the packaging substrate 31. Thermal conductive adhesive 32 may also be provided on the surface of the packaging substrate 31 first, and then the chip 11 and the packaging substrate 31 are fixed by welding. In this way, the thermal conductive adhesive 32 may buffer the stress during the welding process of the chip 11 and the packaging substrate 31, and the warping problem of the chip 11 may be avoided.

The pins 111 of the chip 11 may be fixed by welding to the interconnection circuit 311, and the solder used may be the same material as the solder layer 21. Accordingly, low-temperature welding may be achieved, and the warping problem of the chip 11 caused by high-temperature welding may be avoided.

The stress buffer layer 131 may also be thermal conductive adhesive. Accordingly, thermal contact fixation between the chip 11 and the heat sink 12 may be achieved, heat dissipation efficiency may be improved, and reliable fixation of the chip 11 may be achieved.

In the chip packaging structure provided by one embodiment, the bottom of the thermal conductive protrusion 132 is located on the surface of one of the chip 11 and the heat sink 12. The top of the thermal conductive protrusion 132 may be directly fixed by welding to the other one of the chip 11 and the heat sink 12, or may be fixed by adhesion through a stress buffer layer, to the other one of the chip 11 and the heat sink 12. The surface of the chip 11 facing to the heat sink 12 is the functional surface of the chip. The heat of the chip 11 may be directly dissipated through the heat sink 12 that is in thermal contact with the functional surface. Accordingly, the heat dissipation efficiency of the chip may be improved.

While the chip 11 may dissipate heat through the packaging substrate 31, the chip 11 may also dissipate heat through the heat sink 12. As such, the chip 11 may dissipate heat in two directions, the heat dissipation paths may be increased, and heat dissipation efficiency may be improved.

As an example for illustration, in the approach shown in FIG. 6, the thermal conductive protrusions 132 each are second thermal conductive protrusions 132b disposed on the surface of the chip 11. In this approach, bumps may be directly grown on the surface of the chip 11 as the second thermal conductive protrusions 132b. When the second thermal conductive protrusions 132b need to be fixed by welding to the heat sink 12, the bumps may serve as the thermal conductive base materials 22, and the solder layers 21 may be formed on the bump surfaces.

The chip 11 may be a silicon substrate chip. Metal bumps may be formed on the surface of the chip 11 by using a process, such as sputtering.

FIG. 7 illustrates a schematic diagram of another chip packaging structure consistent with the disclosed embodiments of the present disclosure. Referring to FIG. 7, in one embodiment, the thermal conductive protrusions 132 each are first thermal conductive protrusions 132a provided on the surface of the heat sink 12. In this configuration, bumps may be directly grown on the surface of the heat sink 12 as the first thermal conductive protrusions 132a. When the first thermal conductive protrusions 132a need to be fixed by welding to the chip 11, the bumps may serve as the thermal conductive base materials 22, and solder layers 21 may be formed on the bump surfaces.

In one embodiment, the heat sink 12 is made of a metal material, and may have good thermal conductivity. Accordingly, the heat dissipation efficiency of the heat dissipation path from the chip 11 to the heat sink 12 may be improved.

In each of the configurations shown in FIGS. 1-3, 6 and 7, as an example for illustration, the bottom of the thermal conductive protrusion 132 is located at one of the heat sink 12 and the chip 11, and the top of the thermal conductive protrusion 132 is in direct contact with the other one of the heat sink 12 and the chip 11. In this case, one of the heat sink 12 and the chip 11 is provided with the thermal conductive protrusion 132, and is in direct contact with the other of the heat sink 12 and the chip 11, through the top of the thermal conductive protrusion 132. Accordingly, the heat conduction path may be shortened, and heat dissipation efficiency may be improved.

In some other embodiments, a stress buffer layer 131 may also be provided between the top of the thermal conductive protrusion 132 and the other one of the heat sink 12 and the chip 11. The top of the thermal conductive protrusion 132 does not directly contact the other one of the heat sink 12 and the chip 11. In this case, there is no direct contact between the heat sink 12 and the chip 11, and direct stress transfer between the heat sink 12 and the chip 11 may thus be avoided. Accordingly, stress buffering effect may be improved through the stress buffer layer 131, and the problem of direct contact between the heat sink 12 and the chip 11 that may generate noises on the chip 11 may be avoided. In addition, the thermal conductive protrusions 132 may be prevented from being damaged, and the heat dissipation performance may be improved.

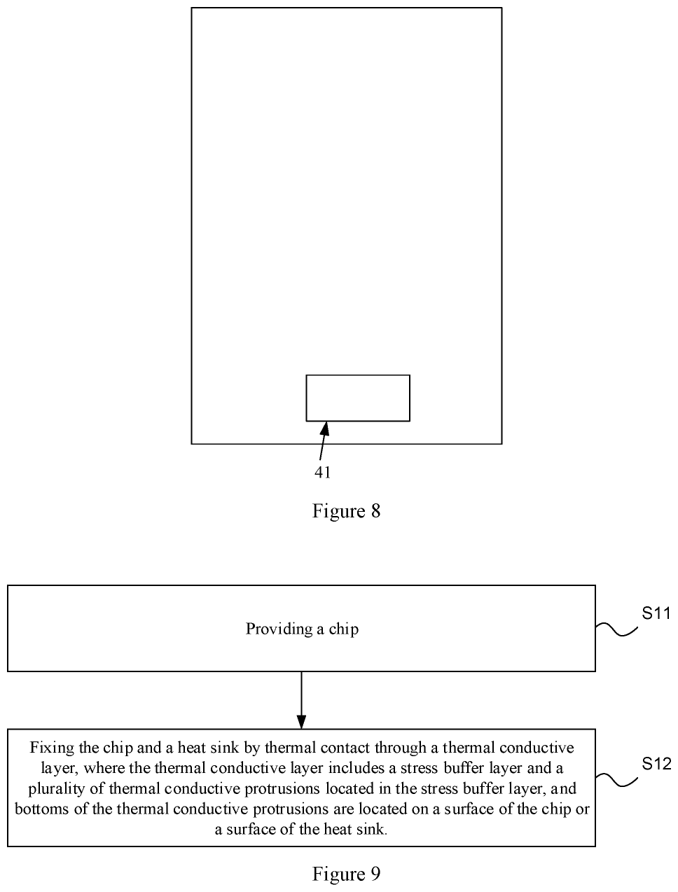

The present disclosure also provides an electronic device. FIG. 8 illustrates a schematic structural diagram of an electronic device consistent with the disclosed embodiments of the present disclosure. Referring to FIG. 8, the electronic device includes a chip packaging structure 41 provided by the present disclosure.

The electronic device may be an electronic device such as a mobile phone, a computer, a home appliance, and a wearable device. The present disclosure does not limit a specific type of electronic device.

In one embodiment, the electronic device adopts the chip packaging structure 41 provided by the present disclosure, and the heat dissipation efficiency of the chip 11 may thus be improved. Accordingly, the chip 11 may operate in a suitable temperature environment, and the safety and reliability of the chip may be improved.

The present disclosure also provides a chip packaging method for preparing the chip packaging structure provided by the present disclosure. FIG. 9 illustrates a method flow chart of a chip packaging method consistent with the disclosed embodiments of the present disclosure. Referring to FIG. 9, the chip packaging method includes:

Step S11: providing a chip.

Step S12: fixing the chip and a heat sink by thermal contact through a thermal conductive layer. The thermal conductive layer includes a stress buffer layer and a plurality of thermal conductive protrusions located in the stress buffer layer. The bottoms of the thermal conductive protrusions are located on a surface of the chip or a surface of the heat sink.

For details of the chip packaging structure prepared based on the chip packaging method provided by the present disclosure, references may be made to the accompanying drawings of the present disclosure. The chip packaging structure prepared may improve the heat dissipation efficiency of the chip.

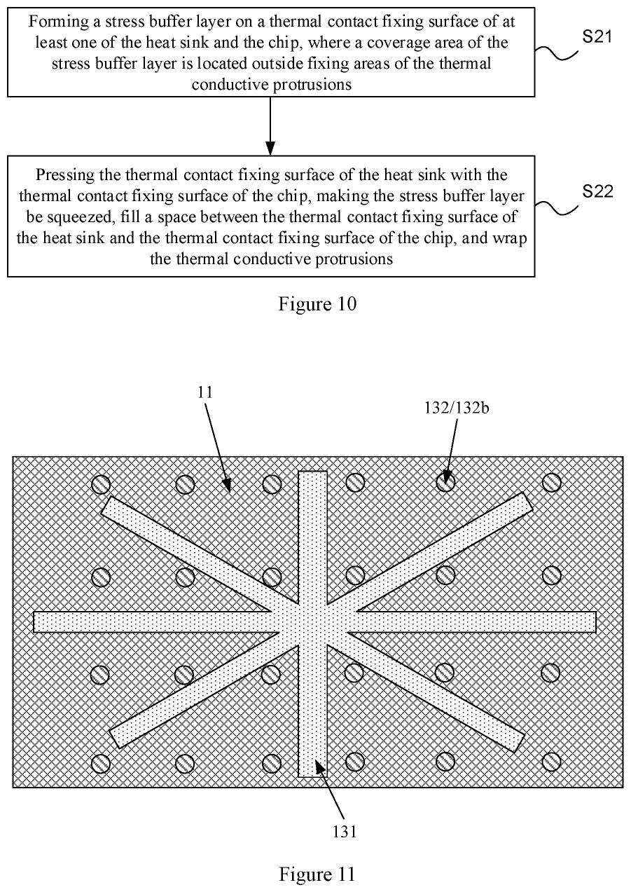

FIG. 10 illustrates a method flow chart for performing thermal contact fixation on a chip and a heat sink through a thermal conductive layer consistent with the disclosed embodiments of the present disclosure. The present disclosure also provides a method for fixing a chip with the heat sink by thermal contact through the thermal conductive layer. As shown in FIG. 10, the method includes:

Step S21: forming a stress buffer layer on a thermal contact fixing surface of at least one of the heat sink and the chip. The coverage area of the stress buffer layer is located outside the fixing area of the thermal conductive protrusions;

Step S22: pressing the thermal contact fixing surface of the heat sink (the side surface of the heat sink facing the chip) with the thermal contact fixing surface of the chip (the side surface of the chip facing the heat sink), making the stress buffer layer be squeezed, fill the space between the thermal contact fixing surface of the heat sink and the thermal contact fixing surface of the chip, and wrap the thermal conductive protrusions.

FIG. 11 illustrates a schematic principle diagram of providing a stress buffer layer on a surface of a chip consistent with the disclosed embodiments of the present disclosure. Referring to FIG. 11, the thermal contact fixing surface of the chip 11 is disposed with second thermal conductive protrusions 132b. Before the chip 11 and the heat sink are fixed by thermal contact, a stress buffer layer 131 is provided on the thermal contact fixing surface of the chip 11. In this case, the coverage area of the stress buffer layer 131 is located outside the fixing area of the thermal conductive protrusions 132. Then, during the thermal contact fixation process of the chip 11 and the heat sink, the stress buffer layer 131 may be squeezed. The stress buffer layer 131 may fill the space between the thermal contact fixing surface of the heat sink and the thermal contact fixing surface of the chip 11, and wrap the thermal conductive protrusions 132.

As shown in FIG. 11, when the tops of the thermal conductive protrusions 132 need to be fixed by welding, the stress buffer layer 131 that does not overlap with the thermal conductive protrusions 132 may be provided before welding. Based on the pressure and temperature during the welding process, the stress buffer layer 131 may completely fill the space between the chip 11 and the heat sink 12.

When the tops of the thermal conductive protrusions 132 do not need to be fixed by welding, the stress buffer layer 131 may be directly laid on the entire surface of the chip 11 or the heat sink 12.

The packaging method provided by the present disclosure is o not limited to the method shown in FIG. 11. The stress buffer layer may also be provided on the thermal contact fixing surface of the heat sink, and then the chip and the heat sink are fixed by thermal contact. Alternatively, after the stress buffer layer is provided on each of the thermal contact fixing surface of the chip and the thermal contact fixing surface of the heat sink respectively, the chip and the heat sink are fixed by thermal contact. The present disclosure does not limit a specific process of thermal contact fixation.

As described above, the chip includes a first surface and a second surface opposite to the first surface. The second surface of the chip faces the heat sink and may be used for thermal contact fixation with the heat sink through a thermal conductive layer. Before fixing the chip with the heat sink by thermal contact, the packaging method also includes: providing a packaging substrate; providing a buffer film on one side surface of the packaging substrate; fixing the first surface of the chip to another side surface of the packaging substrate. The buffer film may be an elastic film, and may buffer stress during the welding process of the chip and the packaging substrate, avoiding the warping problem of the chip 11.

As disclosed, the technical solutions of the present disclosure have the following advantages.

In the chip packaging structure, electronic device and chip packaging method provided by the present disclosure, the chip is packaged through a heat sink, and the heat sink and the chip are fixed by thermal contact through a thermal conductive layer. While the heat sink is used to package and protect the chip, heat dissipation of the chip may be improved simultaneously. Moreover, the thermal conductive layer includes a stress buffer layer and a thermal conductive protrusion located in the stress buffer layer. On the one hand, the stress buffer layer may be used to solve the warping problem of the chip caused by changes in temperature and pressure during the packaging process. On the other hand, the thermal conductive protrusion may increase the thermal contact area between the chip and the heat sink, improving the heat dissipation rate.

The embodiments of the present disclosure are described in a progressive way, or in a parallel way, or in a combination of a progressive way and a parallel way. Each embodiment focuses on its differences from other embodiments, and the same and similar parts between various embodiments may be referred to each other. Since the electronic device and the chip packaging method provided in the present disclosure correspond to the chip packaging structure provided in the present disclosure, descriptions of the electronic device and the chip packaging method are relatively brief. For more detailed information, reference may be made to the relevant description of the chip packaging structure.

It should be noted that, in the present disclosure, descriptions of the accompanying drawings and embodiments are illustrative rather than restrictive. Same drawing reference numerals identify same or like structures throughout the descriptions of the embodiments. For ease of description and understanding, the accompanying drawings may exaggerate thicknesses of some layers, films, panels, regions, etc. In addition, when an element such as a layer, film, region, or substrate is referred to as being “over” another element, the element may be directly on the other element or intervening elements may be present. In addition, “over” refers to positioning an element above or below another element, but does not essentially mean positioning on an upper side of another element according to the direction of gravity.

Terms “upper”, “lower”, “top”, “bottom”, “inner”, “outer”, etc. indicate an orientation or positional relationship based on the orientation or positional relationship shown in the accompanying drawings. These terms are merely for description of the present disclosure and simplification of the description, and are not intended to indicate or imply that the device or element referred to must have a specific orientation, or be constructed or operate in a specific orientation. These terms cannot be construed as a limitation on the present disclosure. When a component is said to be “connected” to another component, the component may be directly connected to another component, or an intermediate component present may exist simultaneously.

It should be noted that in the present disclosure, relational terms such as “first” and “second” are only used to distinguish one entity or operation from another entity or operation, and do not necessarily require or imply that such actual relationship or sequence exists between these entities or operations. Terms “comprise” or “include” or any other variations thereof are intended to cover a non-exclusive inclusion. An item or piece of equipment that includes a set of elements includes not only the set of elements, but also other elements not expressly listed, or elements inherent to this type of items or equipment. Without further limitation, an element defined by a statement like “comprises a . . . ” does not exclude the presence of additional identical elements in an item or piece of equipment that includes the foregoing element.

The embodiments disclosed in the present disclosure are exemplary only and not limiting the scope of the present disclosure. Various combinations, alternations, modifications, or equivalents to the technical solutions of the disclosed embodiments can be obvious to those skilled in the art and can be included in the present disclosure. Without departing from the spirit of the present disclosure, the technical solutions of the present disclosure may be implemented by other embodiments, and such other embodiments are intended to be encompassed within the scope of the present disclosure.

What is claimed is:

1. A chip packaging structure, comprising:
a chip;
a heat sink; and
a thermal conductive layer,
wherein:
the heat sink and the chip are fixed by thermal contact through the thermal conductive layer;
the thermal conductive layer includes a stress buffer layer and a plurality of thermal conductive protrusions located in the stress buffer layer; and
bottoms of the plurality of thermal conductive protrusions are located on a surface of the chip or a surface of the heat sink.

2. The chip packaging structure according to claim 1, wherein:
the bottoms of the plurality of thermal conductive protrusions are in contact with the chip or the heat sink respectively, and the plurality of thermal conductive protrusions includes at least one of a first thermal conductive protrusion and a second thermal conductive protrusion.

3. The chip packaging structure according to claim 2, wherein:
a bottom of the first thermal conductive protrusion is located on the surface of the heat sink, a top of the first thermal conductive protrusion faces the chip, and the top of the first thermal conductive protrusion is fixed to the chip by welding, or fixed to the chip by adhesion through the stress buffer layer.

4. The chip packaging structure according to claim 3, wherein:
a bottom of the second thermal conductive protrusion is located on the surface of the chip, a top of the second thermal conductive protrusion faces the heat sink, and the top of the second thermal conductive protrusion is fixed to the heat sink by welding, or fixed to the heat sink by adhesion through the stress buffer layer.

5. The chip packaging structure according to claim 1, wherein a thermal conductive protrusion of the plurality of thermal conductive protrusions includes:
a thermal conductive base material and a solder layer covering the thermal conductive base material, wherein a melting point of the solder layer is lower than a melting point of the thermal conductive base material.

6. The chip packaging structure according to claim 1, wherein:
a side surface of the chip facing the heat sink includes a first area and a second area, and operating power of a circuit in the first area is greater than operating power of a circuit in the second area; and
in a region where the chip is opposite to the heat sink, the thermal conductive protrusions corresponding to the first area have a first distribution density, and the thermal conductive protrusions corresponding to the second area have a second distribution density, wherein the first distribution density is greater than the second distribution density.

7. The chip packaging structure according to claim 1, wherein:
the heat sink includes a groove, and a sidewall of the groove is sealed and fixed with a packaging substrate, forming a cavity; and
the chip is located in the cavity, and the chip includes a first surface and a second surface opposite to the first surface, wherein the first surface of the chip is fixed on a surface of the packaging substrate, the second surface of the chip faces a groove bottom surface of the heat sink, and the second surface of the chip and the groove bottom surface of the heat sink are fixed by thermal contact through the thermal conductive layer.

8. The chip packaging structure according to claim 7, wherein:
the bottoms of the plurality of thermal conductive protrusions in the thermal conductive layer are located on the second surface of the chip or on the groove bottom surface of the heat sink.

9. The chip packaging structure according to claim 1, wherein:
the stress buffer layer includes thermal conductive adhesive.

10. An electronic device, comprising:
a chip packaging structure including:
a chip; a heat sink; and a thermal conductive layer, wherein:
the heat sink and the chip are fixed by thermal contact through the thermal conductive layer;
the thermal conductive layer includes a stress buffer layer and a plurality of thermal conductive protrusions located in the stress buffer layer; and
bottoms of the plurality of thermal conductive protrusions are located on a surface of the chip or a surface of the heat sink.

11. The device according to claim 10, wherein:
the bottoms of the plurality of thermal conductive protrusions are in contact with the chip or the heat sink respectively, and the plurality of thermal conductive protrusions includes at least one of a first thermal conductive protrusion and a second thermal conductive protrusion.

12. The device according to claim 11, wherein:
a bottom of the first thermal conductive protrusion is located on the surface of the heat sink, a top of the first thermal conductive protrusion faces the chip, and the top of the first thermal conductive protrusion is fixed to the chip by welding, or fixed to the chip by adhesion through the stress buffer layer.

13. The device according to claim 12, wherein:
a bottom of the second thermal conductive protrusion is located on the surface of the chip, a top of the second thermal conductive protrusion faces the heat sink, and the top of the second thermal conductive protrusion is fixed to the heat sink by welding, or fixed to the heat sink by adhesion through the stress buffer layer.

14. The device according to claim 10, wherein a thermal conductive protrusion of the plurality of thermal conductive protrusions includes:
a thermal conductive base material and a solder layer covering the thermal conductive base material, wherein a melting point of the solder layer is lower than a melting point of the thermal conductive base material.

15. The device according to claim 10, wherein:
a side surface of the chip facing the heat sink includes a first area and a second area, and operating power of a circuit in the first area is greater than operating power of a circuit in the second area; and
in a region where the chip is opposite to the heat sink, the thermal conductive protrusions corresponding to the first area have a first distribution density, and the thermal conductive protrusions corresponding to the second area have a second distribution density, wherein the first distribution density is greater than the second distribution density.

16. The device according to claim 10, wherein:
the heat sink includes a groove, and a sidewall of the groove is sealed and fixed with a packaging substrate, forming a cavity;
the chip is located in the cavity, and the chip includes a first surface and a second surface opposite to the first surface, wherein the first surface of the chip is fixed on a surface of the packaging substrate, the second surface of the chip faces a groove bottom surface of the heat sink, and the second surface of the chip and the groove bottom surface of the heat sink are fixed by thermal contact through the thermal conductive layer; and
the bottoms of the plurality of thermal conductive protrusions in the thermal conductive layer are located on the second surface of the chip or on the groove bottom surface of the heat sink.

17. The device according to claim 10, wherein:
the stress buffer layer includes thermal conductive adhesive.

18. A chip packaging method, comprising:
providing a chip;
providing a heat sink; and
fixing the chip and the heat sink by thermal contact through a thermal conductive layer, wherein the thermal conductive layer includes a stress buffer layer and a plurality of thermal conductive protrusions located in the stress buffer layer, and bottoms of the plurality of thermal conductive protrusions are located on a surface of the chip or a surface of the heat sink.

19. The chip packaging method according to claim 18, wherein fixing the chip and the heat sink by thermal contact through the thermal conductive layer includes:
forming the stress buffer layer on at least one of a thermal contact fixing surface of the heat sink and a thermal contact fixing surface of the chip, wherein a coverage area of the stress buffer layer is located outside fixing areas of the plurality of thermal conductive protrusions; and
pressing the thermal contact fixing surface of the heat sink with the thermal contact fixing surface of the chip, making the stress buffer layer be squeezed, fill a space between the thermal contact fixing surface of the heat sink and the thermal contact fixing surface of the chip, and wrap the plurality of thermal conductive protrusions.

20. The chip packaging method according to claim 18, wherein:
the chip includes a first surface and a second surface opposite to the first surface, wherein the second surface of the chip faces the heat sink and is configured for thermal contact fixation with the heat sink through the thermal conductive layer; and
before fixing the chip with the heat sink by thermal contact, the chip packaging method further includes:
providing a packaging substrate;
disposing a buffer film on a side surface of the packaging substrate; and
fixing the first surface of the chip to another side surface of the packaging substrate.
